(19) United States
(12) Patent Application Publication
(10) Pub. No.: US 2024/0318929 A1
(43) Pub. Date: Sep. 26, 2024

(54) Heatsink and device with integrated heatsink

(71) Applicant: International Business and Technology Service Corporation, North Oaks, MN (US)

(72) Inventor: Kaizhong Gao, North Oaks, MN (US)

(73) Assignee: International Business and Technology Service Corporation, North Oaks, MN (US)

(21) Appl. No.: 18/125,710

(22) Filed: Mar. 23, 2023

(51) Int. Cl. F28F 13/18; H05K 7/20

(52) U.S. Cl. CPC F28F 13/185; H05K 7/20409; F28F 2255/20

(57) ABSTRACT

This invention describes a mesoscale heatsink solution, which includes various methods for achieving heatsink structures at the micrometer and nanometer scales, coating materials, and processes to achieve heatsink structures in a cost-effective way. The mesoscale heatsink offers increased efficiency in dissipating heat from devices due to its unique design and critical dimension in the range of 100 nanometers to 100s of micrometers, which increases the heatsink surface area. In one embodiment, this mesoscale heatsink structure can be produced on top of existing heatsinks utilized for electronic devices. In another embodiment, the heatsink structure can be formed using coating materials and directly applied to the device surface or built directly into or integrated with device covers, such as those used for solar modules, inverters, and magnetic hard disk drives.

### RELATED APPLICATION

N/A. This is the first patent application draft.

### FIELD OF THE DISCLOSURE

The present disclosure relates to a novel integrated heatsink design, materials, structure, and processes for achieving nano or micro-scale heatsinks for device apparatus, particularly for semiconductor device apparatus and power electronic device apparatus. The integrated heatsink is designed to improve the efficiency and lifetime of the devices and for data storage devices, to improve data reliability and reduce operating costs.

### BACKGROUND

Modern electronic devices have become increasingly efficient over time, thanks to advances in design and manufacturing processes, as well as Moore's law. However, in many applications, it is desirable to have a heatsink structure that can be used with the device to improve its efficiency, performance, reliability, and lifetime.

One application is for modern semiconductor devices, such as the Central Processing Unit (CPU), Graphics Processing Unit (GPU), Accelerated Processing Unit (APU), Tensor Processing Unit (TPU), Data Processing Unit (DPU), Neural Processing Unit (NPU), and other semiconductor chipsets or processing units. In this application, a dedicated heatsink is attached to the device. Typically, a fan blows air onto the heatsink, rapidly moving hot air away from the device. The heatsink consists of a high thermal conductive surface that can be in close contact with the chip backend surface, and a number of fin structures with thermal conductive channels. In passive mode, the heatsink dissipates heat to the surrounding air directly. In active mode, a fan blows the air along the direction parallel to the fin surface, which effectively removes heat away from the heatsink surface. Regardless of the detailed design and application, the heatsink structure has a large number of fin structures to increase the surface area in contact with the air.

Another application is for power electronic and energy conversion devices, such as inverters or solar modules. For large capacity inverters, the heatsink is added using a similar approach as semiconductor devices. However, for micro inverters and solar modules, there are limited options to provide additional heatsink functions.

Most electronic devices generate heat during operation, and this heat can be dissipated under normal conditions, eliminating the need for a heatsink. However, in cloud data centers, where a large number of hard disk drives (HDD) are packed into a confined space, heat dissipation can become an issue. Despite active air flow provided by the room ventilation or HVAC system, it is desirable to have a solution that effectively removes heat from HDDs.

There are many benefits to using heatsinks for semiconductor chips, such as CPUs or GPUs, etc. A heatsink effectively lowers the temperature, which not only protects the chip but also allows the chip to run at a higher clock speed, resulting in higher performance or computational speed. For solar modules, lower cell temperature raises conversion efficiency (CE) and reduces their failure rate, enabling a significantly longer lifetime. For inverters, lower operating temperatures improve efficiency, prevent derate, increase energy production, and extend device lifetime. For HDDs in data centers, lower drive temperatures improve data reliability and operational efficiency.

There is a great opportunity for materials and design solutions that can be applied to power electronic devices or semiconductor device surfaces to improve heat dissipation. In some applications, an effective solution can also provide additional protection to the device. For example, for solar modules with cracked backsheets, an effective heatsink solution can be a valid way to fix solar modules that have already experienced cracked backsheets in the field. However, there is a lack of effective solutions to achieve enhanced heatsink function in a cost-effective way.

### SUMMARY

The disclosed embodiments provide a solution for enhancing heatsink efficiency in various applications by increasing the heatsink contact area without adding significant materials weight and cost. The heatsink structure described herein addresses these disadvantages and provides a device solution for enhancing heatsink efficiency compared to the current heatsink structures used in the semiconductor industry and power electronic industry. The solution disclosed here effectively increases the heatsink contact area by 2-3× compared to the current heatsink structures used in the field, without adding materials weight and cost. The disclosed embodiments are suitable for use in many applications, particularly for CPU, GPU, and other semiconductor chips, as well as for power electronic devices. In another embodiment, the heatsink structure can be directly integrated into the device surface and utilized for solar modules, HDDs, inverters, or optimizers. This later provides an enhanced heatsink property, effectively lowering the device operating temperature by up to 15%. In addition, the heatsink can be applied to existing devices, such as solar modules to repair damaged surfaces and extend their lifetimes. The same heatsink solution can also be utilized in other electronic devices, such as HVAC (include chiller and cold water pipe)/Furnace (include boiler and hot water pipe), where rapid dissipation of heat or cool air is desired.

Throughout this disclosure, the terms “doping materials” and “dopants” refer to the same concept of adding a relatively small amount (by weight) of solid materials/particles with predetermined particle size or size distribution to liquid-based coating materials. In this context, “doping materials” or “dopants” refer to the solid particles. The term “particle size” refers to the diameter of the particles, and “size distribution” refers to the distribution of particle sizes or grain sizes.

The term mesoscale used here is typically refers to the length between 100 nanometer to 100 micrometer, which is typically larger than the nanoscale people often refers to, but smaller than the traditional heatsink critical dimension such as fin thickness (˜0.2 millimeter or higher), or fin surface dimension (˜ centimeters). In some cases, it can refer to a range between 50 nanometers to 200 micrometers.

### BRIEF DESCRIPTION OF THE DRAWINGS

The detailed description and accompanying drawings will help to fully understand the various aspects and advantages described in this disclosure. The drawings are considered a part of this specification and depict exemplary embodiments of the invention, which may take various forms. It is important to note that some aspects of the invention may be shown in an exaggerated or enlarged manner in order to facilitate understanding, and as such, the drawings may not necessarily be to scale. In the embodiments illustrated herein, similar reference numerals in different drawings refer to the conceptual design of structural elements representing each particular component or element of the apparatus.

FIG. 1a is a perspective view of a typical heatsink;

FIG. 1b is a side view of a typical heatsink;

FIG. 2 shows one embodiment of the proposed heatsink structure;

FIG. 3 shows another embodiment of the proposed heatsink structure;

FIG. 4 shows yet another embodiment of the proposed heatsink structure;

FIG. 5 shows still another embodiment of the proposed heatsink structure;

FIG. 6 illustrates the heatsink surface topology in one embodiment of the proposed heatsink solution;

FIG. 7 shows the heatsink critical dimension aspect ratio vs. surface areas in one embodiment of the proposed heatsink solution;

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### DETAILED DESCRIPTION

In the following description, numerous specific details are disclosed to provide a thorough understanding of embodiments of the method, system and apparatus. One skilled in the relevant art will recognize, however, that embodiments of the method, system and apparatus described herein may be practiced without one or more of the specific details, or with other electronic devices, mechanic devices, methods, components, and materials, and that various changes and modifications can be made while remaining within the scope of the appended claims. In other instances, well-known electronic devices, mechanical devices, components, structures, materials, operations, methods, process steps and the like may not be shown or described in detail to avoid obscuring aspects of the embodiments. Embodiments of the apparatus, method and system are described herein with reference to figures.

Reference throughout this specification to “one embodiment,” “an embodiment,” or similar language means that a particular feature, structure, electronic device, method or characteristic described in connection with the embodiment is included in at least one embodiment. Thus, appearances of the phrases “in one embodiment,” “in an embodiment,” and similar language throughout this specification may refer to separate embodiments or may all refer to the same embodiment. Furthermore, the described features, structures, methods, electronic devices, mechanical devices or characteristics may be combined in any suitable manner in one or more embodiments.

Referring to the figures wherein identical reference numerals denote the same elements throughout the various views.

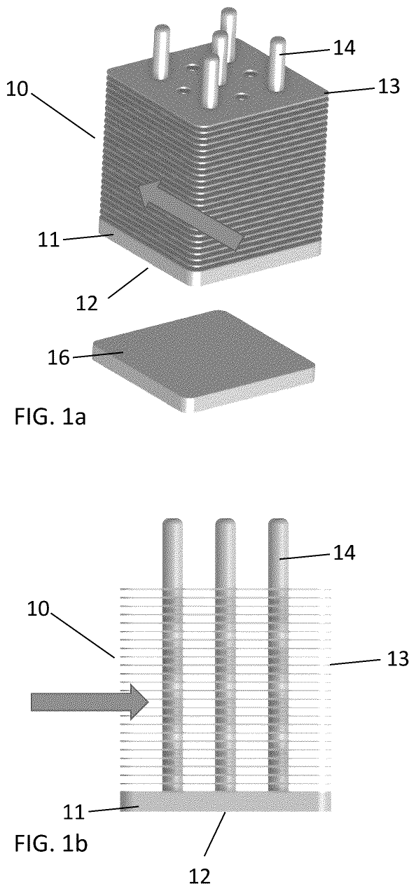

FIG. 1a shows a typical heatsink 10 used in the semiconductor industry for GPUs or CPUs. In this example, we assume the heatsink is applied to a GPU unit. The heatsink 10 consists of a highly thermally conductive base 11 with a surface 12 (not shown here) that can be in close contact with the chip backend surface 16 and a large number of fin structures 13 with large thermally conductive channels 14. In practice, thermal paste (not shown here), typically consisting of highly thermally conductive gel (optional), is applied between the heatsink base 11 and the GPU backend surface 16. During operation, a fan (not shown here) blows air onto the heatsink (in the direction of the arrow), rapidly moving the air away from the device. In practice, the fan blows the air along the direction parallel to the fin surface, which effectively removes heat away from the heatsink structure. If the airflow can be maintained at a certain level, then the heatsink efficiency is proportional to the surface area in contact with the air. Therefore, typical heatsinks have a large number of fins. However, once the number of fins is large, the spacing between the fins is reduced, and at a certain point, the airflow speed is reduced. Therefore, modern heatsink designs have to optimize between fan speed, power consumption, number of fins, and spacing. The fin structure can be optimized in different shapes, but typically, the fin structure has a high aspect ratio, with thickness less than 0.5 mm but higher than 0.2 mm to maintain a large surface area, reduce weight, and maintain its mechanical structure, while the other two dimensions are kept large in order of several centimeters. The conductive channels 14 are typically high thermally conductive heat pipes or rods, such as copper or aluminum pipes, which effectively conducts heat from the heatsink base 11 to each layer of fins. In practice, the heat pipes design, size and shape can be in different ways. The conductive channel 14 or the heat pipes starts from the heatsink plate 11, and maintains its close contact with each layer of fin 13 to spread heat quickly. In some designs, the conductive channel 14 spread out from the heatsink base 11 before the first fin 13 layer is in contact, to allow a larger fin structure to be built. The materials utilized for heatsink are typically high thermal conductive materials, such as copper or aluminum, or its lamination or alloys.

FIG. 1b shows a side view of a typical heatsink 10. From this angle, there is finite spacing between each fin 13. Therefore, when the fan blows air through the spacing between neighboring fins (arrow direction), the rapid airflow can effectively remove heat from the heatsink, thus lowering the chip temperature. For this particular example, the increased surface area due to fin structure 13 is equal to the number of fins multiplied by the individual fin size and then multiplied by two, since each fin has two surfaces. Thus, when the number of fins increases, the surface area is monotonically increased. As mentioned earlier, for the same heatsink size, the spacing between different fins is reduced with increasing number of fins. Therefore, on the one hand, the fin thickness is reduced to be as thin as possible. On the other hand, the number of fins can be increased depending on the air speed from the fan. However, too thin fin thickness will cause the heatsink to be unable to support itself, thus there is a lower limit, typically around 0.3 mm. Therefore, effective heatsinks have fin structures with thicknesses between 0.25-0.5 mm and other dimensions that extend to a few centimeters. A heatsink with 20 fins potentially adds 40 times the surface area, providing an effective heatsink property to lower the CPU and GPU temperature.

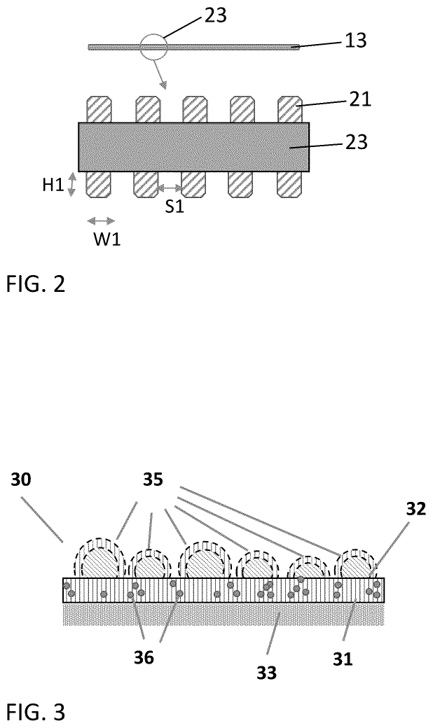

FIG. 2 shows one embodiment of the proposed heatsink structure that can be used in the same or similar design as the heatsink shown in FIG. 1. To illustrate the proposed solution, one layer of fin 13 is taken out from the heatsink 10 and zoomed in. A small section 23 of one piece of heatsink fin 13 is shown. The proposed solution involves integrating a mesoscale heatsink structure 21 onto the surface of the heatsink fins. This mesoscale heatsink creates a rough surface on the heatsink, which further increases the surface area in contact with the air. In this example, a mesoscale groove structure 21 is utilized. Unlike traditional heatsink structures, the width W1 and height H1 of the mesoscale grooves are typically between 50 nm to 200 micrometer, which is smaller than the traditional heatsink fin structure. In a preferred embodiment, the width W1 and height H1 of the mesoscale grooves are within the range of 100 nm to 50 micrometer, and the spacing S1 between neighboring grooves is approximately the same as their width and height. In practice, the space S1, the height H1 and the width H1 can be different, but are within the same order of magnitude.

Using this structure, the heatsink produced will have approximately twice the surface area without increasing the number of fins or reducing the spacing between fins. The thermal paste provides excellent contact between the electronic device and the heatsink structure. The increased surface area for the mesoscale heatsink structure led to significant efficiency improvements and potential temperature reductions of up to 30%.

Depending on the materials used for the heatsink, there are several different ways to achieve the desired mesoscale patterns, such as pressing or stamping processes. Hot pressing or hot embossing can be used to create precise and regular patterns on the surface of the fins. Alternatively, chemical etching and anodization, or powder coating can be used to achieve a rough surface with different surface structures. The detailed design of the mesoscale heatsink surface can vary, and may take the form of groove structures, goosebump structures, pin fin structures, a herringbone structure, or a random rough surface with desired waviness. The process to achieve the desired mesoscale heatsink will depend on the target size and roughness.

The doping particles may include different oxide materials, including Titanium oxide, aluminum oxide, zinc oxide and silicon oxide etc. to provide different materials properties to further provide protection of the solar module as well as enhance its performance. This heatsink structure can be directly applied to the device surface and increase the surface area of the backsheet, and reduce solar module operation temperature.

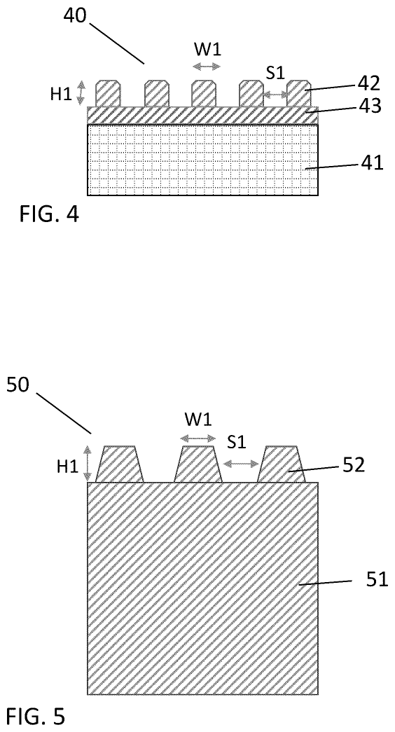

FIG. 3 shows another embodiment of the proposed heatsink structure. The heatsink coating material 30 includes a sheet surface or adhesive layer 31 and a rough surface 32 to increase its surface area exposed to the air. This particular example can be used to apply to solar modules. The adhesive layer 31, also called the base coat, includes polymer-based materials that can directly bond to the solar module backsheet 33. In FIG. 3, a small section of the solar module backsheet is shown as 33. The backsheet typically comprises various polymer or plastic materials such as polypropylene (PP), polyethylene terephthalate (PET), polyvinyl fluoride (PVF), and polyvinylidene fluoride (PVDF), which offer different levels of protection, thermal stability, and long-term UV resistance.

The rough surface 32 is achieved by utilizing different doping materials 35 with desired particle sizes typically between 20-150 micrometers to create the desired texture. Since the typical adhesive layer 31 thickness is on the order of a few 10s of micrometers, particles that are too big or small will either not create the desired surface or not be able to bond well with the base coat 31. There are other small particles 36 may be used and mixed with the adhesive layer 31 to provide additional functionality to improve coating materials thermal, electrical, mechanical properties and improve its performance and lifetime. When mixing the doping particles 35 into the base coat, the particles are covered with base coat materials. Therefore, the rough surface 32 has base coat materials exposed to the air, and the doped particles 35 provide surface rough texture and increase the surface area. In the FIG. 3, the particles 35 are covered by base coat materials.

The doping particles may include different materials, such as titanium oxide, aluminum oxide, zinc oxide, silicone dioxide, calcium carbonate, feldspar, and iron oxide, to provide different material properties and further protect the solar module while enhancing its performance. This mesoscale heatsink structure 30 can be directly formed on the device surface 33, increasing the surface area of the device. In this example, it increases the surface area of the backsheet and reduces the solar module's operating temperature.

FIG. 4 shows another embodiment of the proposed mesoscale heatsink from a side zoom in view. Similar to the first embodiment, this mesoscale heatsink 40 is integrated with the device's outer surface 41. In this case, the groove structure 42 or goosebump surface structure (not shown) is directly built during the backsheet manufacturing process, eliminating the need for an additional adhesive layer. The desired structure is created on the backsheet 43 during manufacturing, after which it is shipped to the PV module manufacturer for use in PV module production. Regardless of what specific features used to create mesoscale heatsink surface 42 with increased surface area, the critical dimensions such as width W1, height H1 and spacing between features S1 is typically between 50 nanometers and a few hundreds of micrometers. In a preferred embodiment, the feature preferred dimension is between 10 to 50 micrometers.

This design concept can also be utilized for other electronic device components, such as the HDD cover plate. A stamping process or mold can be created with predefined texture or structure, so the HDD cover plate outer surface will have a desired built-in structure 42 at the mesoscale, which increases its surface area. When such HDDs are utilized in data centers, the flowing air particles have more efficient heat exchange, enhancing the cooling efficiency for the HDDs and improving data reliability. This approach can reduce data center operation costs and improve data reliability on drives.

FIG. 5 presents another embodiment of the proposed mesoscale heatsink where the integrated mesoscale heatsink is formed on the inverter surface directly. A zoom in of a cross section of the device cover 51 is shown. In an embodiment, the mesoscale heatsink structure is directly integrated with the device cover using a mold with a predefined heatsink structure.

The desired materials, such as polycarbonate and Acrylonitrile Butadiene Styrene (ABS), are used to form the device cover 51 with the embedded heatsink structure during manufacturing. Since the device cover 51 is typically large as compared to the critical dimension of the mesoscale heatsink features (<millimeters), around tens of centimeters, the embedded heatsink structure critical dimensions like groove size, width W1, and depth H1 can be in the range of tens to hundreds of micrometers, allowing for the mold's cost-effective production. Other methods like laser engraving and chemical etching can also be used depending on the application's requirements. With this approach, the device's surface area in contact with air increases, leading to faster heat dissipation without the need for a fan, compared to current approaches. For large capacity inverters, this embodiment and the first embodiment can be combined and utilized.

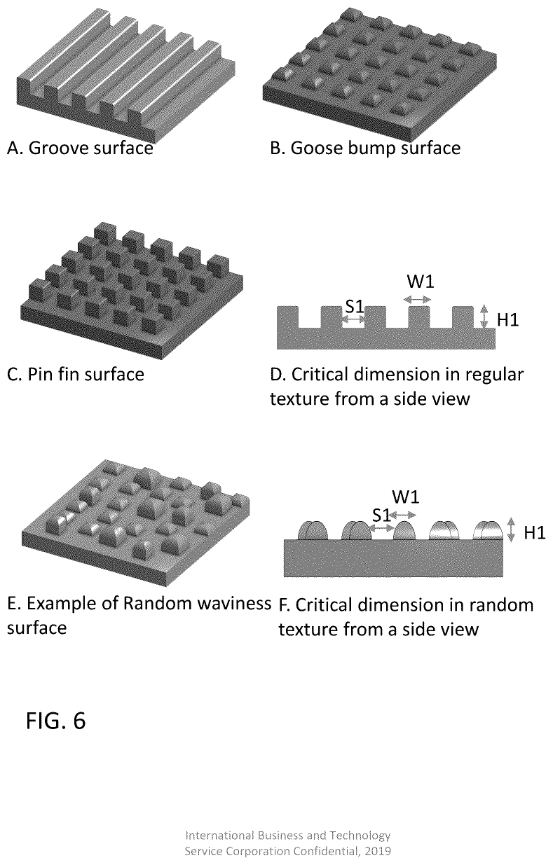

FIG. 6 illustrates the surface topology of the mesoscale heatsink in a few embodiments of the proposed solution in zoom in view. The heatsink typically has a groove (or fin) surface (A), which, due to its small size, may have curved corners and grooves that are not parallel to each other. Alternatively, the heatsink may be based on a pin fin structure (C), which, because of its smaller height, can be characterized as a goosebump structure (B), particularly if the pins are not placed in a regular lattice (E). If utilized as a heatsink with a fan, and the direction of airflow is known, then a particular design such as a herringbone structure (not shown here) can be utilized to further improve cooling efficiency. Another common type of surface topology is randomly rough, which can be achieved by placing nano or micro particles within the base coat. One example of the random rough surface is shown in E, except the actual rough surface may have waviness (not shown here) with height varies from place to place. Although different designs may vary, the mesoscale heatsink can be applied directly with close contact or integrated with existing heatsinks or electronic devices. The critical dimension of the mesoscale heatsink features are still defined as the feature height, width and spacing in between (D). In case the features occur randomly in space, it refers to the average change in height, width or diameter and the spacing between features (F). Such as for a random rough surface, the waviness height is one of the critical dimensions. The cross section of the features of the mesoscale heatsink, particular for designed patterns, can be in any shape, such as rectangle shape, trapezoid, half circle, half elliptical, triangle, etc. The corners may be rounded at a smaller scale due to process choice. The primary benefit of the mesoscale heatsink is the increased surface area with built in mesoscale features and improved heatsink efficiency by feature design. For mesoscale heatsink, one of the key differences as compared to the conventional heatsink is that the features are in the mesoscale range, which can be integrated to existing device surface or heatsink with minimal relative weight change or materials added. The overall design of the device itself does not need to be changed.

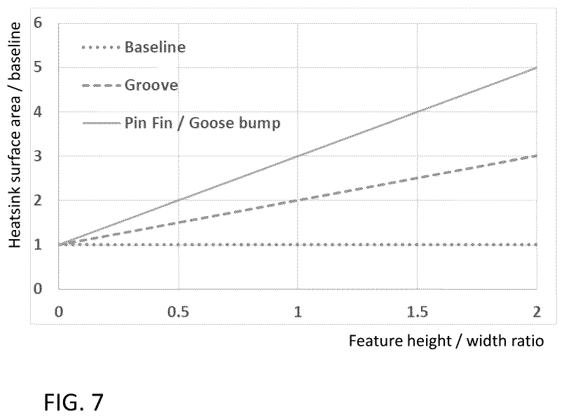

In FIG. 7, we can see the impact of mesoscale heatsink structure on the critical dimension aspect ratio vs. surface areas. Groove and pin fin structures are used to illustrate this effect. By keeping the separation, thickness, and height of the groove the same, one can effectively double the surface area if the filling factor is 50%. On the other hand, using pin fin or goosebump structures with the same critical aspect ratio can increase the surface area up to three times when the filling factor is 50%. Here, the filling factor is defined for the space mesoscale heatsink features occupied; the percentage is occupied by the feature vs. total space. Therefore, the filling factor of 50% represents the region in space that was half filled by the mesoscale heatsink features, and the other half is connected with the open space. This will not lead to significant penalty for airflow, thus the heatsink improves its efficiency due to surface area increase dramatically.

It should be noted that for groove structures, the air flow direction has a preferred direction, which needs to be taken into consideration for applications such as GPUs and CPUs with a fan. The proper design of groove structures enables an effective heatsink with doubled surface area, without changing the existing heatsink design and fan setup. Pin fin, herringbone, or goosebump structures may offer more flexibility for optimization. The herringbone structure may provide better efficiency if aligned with the correct air flow direction. Additionally, depending on the process to achieve, an increase in critical dimension, particularly the height-to-width and spacing ratio, may lead to additional surface area increase. However, when such aspect ratios increase to a too high value, the airflow may be limited. An optimal aspect ratio is between 1:3 and 3:1. In practice, the aspect ratio around 1:1 provides a balance between improved heatsink efficiency and process cost or complexity. When the rough surface does not follow regular patterns, the percentage increase of surface area may not be as significant. However, for mesoscale heatsink structures, once the total surface area increase exceeds 30% or more, significant heatsinking efficiency improvement can be expected. One of the primary benefits of mesoscale heatsinks is that the total heatsink feature size, in terms of volume, is significantly smaller than any of the traditional heatsink structures. It not only minimizes materials cost, boosts efficiency, but also increases surface area without taking up much space. Thus, the gain in heatsink efficiency is a net improvement compared to the conventional approach.

One of the key benefits of the mesoscale heatsink is that the heatsink efficiency highly depends on the percentage of surface area increase, and using the same structure to reduce the critical dimension of the feature size while keeping the aspect ratio will not lead to a surface area penalty. Therefore, depending on the application and process capability, it is possible to reduce heatsink size (volume) dramatically, thus leading to minimal added materials cost. Due to its small size and compatible process with existing device cover, component, or heatsink manufacturing processes, it can be directly integrated into existing devices and realize its benefits with negligible manufacturing cost increase. For applications that require significant effort to dissipate heat, such as for CPUs and GPUs, doubling the surface area without changing heatsink size and design provides significant benefits in terms of improving performance.

Depending on different product applications or focuses, one or more types of the heatsink may be utilized in different products. Therefore, one or more of the above-mentioned designs and processes may be utilized. The embodiments were chosen and described to best explain the principles of the invention and its practical application to persons who are skilled in the art. As various modifications could be made to the exemplary embodiments, as described above with reference to the corresponding illustrations, without departing from the scope of the invention, it is intended that all matter contained in the foregoing description and shown in the accompanying drawings shall be interpreted as illustrative rather than limiting. Thus, the breadth and scope of the present invention should not be limited by any of the above-described exemplary embodiments, but should be defined only in accordance with the following claims appended hereto and their equivalents.

The following list of aspects reflects a variety of the embodiments explicitly contemplated by the present application. Those of ordinary skill in the art will readily appreciate that the aspects below are neither limiting of the embodiments disclosed herein, nor exhaustive of all of the embodiments conceivable from the disclosure above, but are instead meant to be exemplary in nature.

1. A heatsink for dissipating heat from a device, comprising a mesoscale heatsink structure formed on a surface of the device, the conventional heatsink fin surfaces or the heat exchanger surfaces, with features having a critical dimension in the range between 50 nanometers to 100s of micrometers.

2. The mesoscale heatsink of aspect 1, comprising at least one of a groove structure, a fin structure, a pin fin structure, a herringbone structure, a goosebump structure, a random waviness structure, or any other predefined structure to increase the surface area in contact with air for a given device surface.

3. The mesoscale heatsink of aspect 1, wherein the critical dimension includes the width, height, and spacing between heatsink structures, as well as the roughness or height measured from the heatsink plane surface.

4. The mesoscale heatsink of aspect 1, wherein the mesoscale heatsink structure includes a base coat and is further configured to include at least one of the following: doping with nano or micro particles, or a polymer with high thermal conductivity.

5. The mesoscale heatsink of aspect 4, wherein the base coat has a thickness of between 1 and 100 micrometers.

6. The mesoscale heatsink of aspect 4, wherein the doping particles have an average diameter ranging between 50 nanometers and 100s of micrometers or between 100 nanometers and 50 micrometers.

7. The mesoscale heatsink of aspect 4, wherein the size of the doping particles exceeds the thickness of the base coat.

8. The mesoscale heatsink of aspect 4, wherein the doping particles can be made of various materials, including titanium oxide, aluminum oxide, zinc oxide, silicone dioxide, calcium carbonate, feldspar, iron oxide, limestone, magnesium carbonate (dolomite), silicon dioxide (SiO₂), titanium dioxide (TiO₂), iron oxide (Fe₃O₄), clay, iron carbonate, pyrite, quartz, different aluminum, iron, metallic alloys, metallic oxide, or a mixture of one or more of the above materials.

9. The mesoscale heatsink of aspect 4, wherein the base coat also comprises binders based on one or more of the following: latex binders, 100% acrylic, styrene acrylic, or vinyl acrylic; Alkyd (oil) based binders such as linseed oil, tung oil, and soya oil.

10. The mesoscale heatsink of aspect 4, wherein the base coat is a thin film-based coating material; the average diameter of at least one of the doping particles is larger than 20% of the base coat thickness and smaller than 2000% of the base coat thickness.

11. The mesoscale heatsink of aspect 4, wherein the thickness of the base coat is between 1 micrometer and 100 micrometer.

12. The mesoscale heatsink of aspect 4, wherein the base coat materials are selection of acrylic based paint or coating materials, oil based or latex based coating materials, or other coating materials.

13. The mesoscale heatsink of aspect 4, wherein the base coat further includes the binders that are based on one or more of the following, such as: the latex binders, 100% acrylic, styrene acrylic or vinyl acrylic; the Alkyd (oil) based binders, such as linseed oil, tung oil, and soya oil.

14. The mesoscale heatsink of aspect 4, wherein the average diameter of at least one type of the doping particles is larger than 50% of the base coat thickness and smaller than 400% of the base coat thickness.

15. The mesoscale heatsink of aspect 4, wherein the average diameter of the doping particles is larger than 80% of the base coat thickness and smaller than 300% of the base coat thickness.

16. The mesoscale heatsink of aspect 4, wherein the doping particles are made of naturally exist or manmade materials, including one or more of the following: Limestone, calcium carbonate (CaCO₃), magnesium carbonate (dolomite), silicon dioxide (SiO₂), titanium dioxide (TiO₂), Iron oxide (Fe₃O₄), clay, iron carbonate, feldspar, pyrite, quartz, different aluminum, iron, metallic alloys, metallic oxide, or the mixture of one or more of the materials above.

17. The mesoscale heatsink of aspect 4, wherein further comprises additional doping powders with the average diameter less than half of the base coat thickness.

18. The mesoscale heatsink of aspect 4, wherein the mix ratio between the doping powders and the base coat is between 2 grams of doping powders per one gallon of base coat to 500 grams of doping powders per one gallon of base coat.

19. The mesoscale heatsink of aspect 4, wherein the mix ratio between the doping powders and the base coat is between 10 grams of doping powders per one gallon of base coat to 200 grams of doping powders per one gallon of base coat.

20. The mesoscale heatsink of aspect 4, wherein the mix ratio between the doping particles and the base coat is between 5 grams of doping particles per one gallon of base coat to 500 grams of doping particles per one gallon of base coat.

21. The mesoscale heatsink of aspect 4, wherein the mix ratio between the doping particles and the base coat is between 10 grams of doping particles per one gallon of base coat to 500 grams of doping particles per one gallon of base coat.

22. The mesoscale heatsink of aspect 4, wherein the thickness of the base coat is between 5 micrometers and 40 micrometers.

23. The mesoscale heatsink of aspect 4, wherein the average diameter of the doping particles is between 10 micrometers and 60 micrometers.

24. A method of manufacturing a mesoscale heatsink structure for dissipating heat from a device, comprising: forming a mesoscale heatsink structure on a surface of the device, the conventional heatsink fin surfaces or the heat exchanger surfaces, wherein the mesoscale heatsink structure has a critical dimension in the range of between 50 nanometers to 100s of micrometers, and comprises at least one of: a groove structure, a fin structure, a pin fin structure, a herringbone structure, a goosebump structure, a random waviness structure or any other predefined structure to increase the surface area in contact with air.

25. The method of aspect 24, wherein the mesoscale heatsink structure is formed by applying heatsink materials, including a base coat and doping particles or polymers with high thermal conductivity.

26. The method of aspect 25, wherein the doping particles have an average diameter ranging from 2 micrometers to 100 micrometers.

27. The method of aspect 25, wherein the doping particles can be made of various materials, including titanium oxide, aluminum oxide, zinc oxide, silicone dioxide, calcium carbonate, feldspar, iron oxide, limestone, magnesium carbonate (dolomite), silicon dioxide (SiO2), titanium dioxide (TiO₂), iron oxide (Fe₃O₄), clay, iron carbonate, pyrite, quartz, different aluminum and iron metallic alloys, metallic oxides, or a mixture of one or more of the above materials.

28. The method of aspect 25, wherein the heatsink coating layer is based on premixed materials with the doping particles mixed into the base coat; with the application method based on one of the following: spray coating, spray painting, spin coating, roller painting and brush painting.

29. The method of aspect 25, wherein the heatsink coating materials are further mixed with additional liquid materials to enable uniform spread of the coating materials on device surface.

30. The method of aspect 25, wherein the coating layer is applied to a device surface with cracked or damaged surface layer, such as a solar module with cracked backsheet.

31. The method of aspect 24, wherein the mesoscale heatsink structure is formed by using molds, laser engraving, stamping, pressing, chemical etching, powder coating, anodization, or hot pressing methods on the heatsink fin surface or the device component surface.

32. The method of aspect 31, wherein a premade template is used to create mesoscale heatsink structure for molds, stamps for molds, stamping or hot pressing.

33. The method of aspect 24, wherein the critical dimension includes the width, height, and spacing between heatsink feature structures, as well as the roughness or height measured from the heatsink plane surface.

34. A device comprising a mesoscale heatsink for dissipating heat, the heatsink structure comprising: a mesoscale heatsink structure formed on a surface of the device or attached to the heatsink of the device, the mesoscale heatsink structure having a critical dimension in the range of 50s of nanometers to 100s of micrometers, and comprising at least one of: a groove structure, a fin structure, a pin fin structure, a herringbone structure, a goosebump structure, a random waviness structure or any other predefined structure to increase the surface area in contact with air.

35. The device of aspect 34, wherein the mesoscale heatsink structure is embedded or integrated with a device component surface, such as a top plate cover for a hard disk drive (HDD).

36. The device of aspect 34, wherein the mesoscale heatsink structure forms a pattern on the device surface including product information, i.e. form letters or graphs.

37. The device of aspect 34, wherein the surface with the mesoscale heatsink structure is the backsheet for a solar module.

38. The device of aspect 37, wherein the mesoscale heatsink layer applied on the solar module back sheet comprises a base coat and doping particles mixed together.

39. The device of aspect 38, wherein the base coat is a thin film-based coating material; the average diameter of the doping particles is larger than 20% of the base coat thickness and smaller than 2000% of the base coat thickness.

40. The device of aspect 37, wherein the heatsink layer base coat thickness is between 1 micrometer and 100 micrometer.

41. The device of aspect 37, wherein the heatsink base coat materials are a selection of acrylic based paint or coating materials, oil based or latex based coating materials, or other coating materials.

42. The device of aspect 37, wherein the heatsink layer includes a base coat and doping particles, wherein the doping particles are made of naturally exist or manmade materials, including one or more of the following: Limestone, calcium carbonate (CaCO₃), magnesium carbonate (dolomite), silicon dioxide (SiO₂), titanium dioxide (TiO₂), Iron oxide (Fe₃O₄), clay, iron carbonate, feldspar, pyrite, quartz, different aluminum, iron, metallic alloys, metallic oxide, or the mixture of one or more of the materials above.

43. The device of aspect 37, wherein the heatsink layer has the doping particles and the base coat premixed, with the mix ratio between 5 grams of doping particles per one gallon of base coat to 500 grams of doping particles per one gallon of base coat.

44. The device of aspect 37, wherein the heatsink layer has an uneven surface, a surface with goosebumps, fins, ridges, fingers or zigzag structures.

45. The device of aspect 37, wherein the heatsink total thickness is 1 mm or less.

46. The device of aspect 37, wherein the heatsink layer applied to the back sheet; the back sheet outer surface that is in contact with the heatsink layer is made of one or more of the following: Polypropylene (PP), polyethylene terephthalate (PET), Polyvinyl fluoride (PVF), ionomer, nylon or other polymer materials.

47. The device of aspect 37, wherein the heatsink coating materials further comprises additional doping powders with the average diameter less than half of the base coat thickness.

48. The device of aspect 37, wherein the heatsink coating materials has the mix ratio between the doping powders and the base coat is between 2 grams of doping powders per one gallon of base coat to 500 grams of doping powders per one gallon of base coat.

49. The device of aspect 37, wherein the thickness of the base coat is between 5 micrometers and 50 micrometers.

50. The device of aspect 37, wherein the average diameter of the doping particles is between 10 micrometers and 60 micrometers.

51. The device of aspect 34, wherein the surface of the mesoscale heatsink structure is formed using coating materials with a base coat and doping particles with the average diameter between 2 micrometers to 100 micrometers.

52. The device of aspect 34, wherein the surface with the mesoscale heatsink structure is formed on device cover, such as for an energy conversion device, an inverter, an optimizer or a micro-inverter.

53. The device of aspect 52, wherein the mesoscale heatsink structure is formed on device cover using mold with predefined texture.

54. The device of aspect 34, wherein the surface with the mesoscale heatsink structure is a cover plate or is formed on device cover, such as for an HDD, an energy conversion device, an inverter, an optimizer, or a micro-inverter.

55. The device of aspect 34, wherein the surface with the mesoscale heatsink structure is the backsheet for a solar module.

56. The device of aspect 34, wherein the surface with the mesoscale heatsink structure is formed on top of existing heatsink structure or heat exchanger structure, such as the surface of the heatsink fins or heat exchanger surface such as used in HVAC (evaporator coils and/or condenser coils), furnace, fan coil unit or air handler unit etc.

57. The mesoscale heatsink of aspect 1, wherein the features size has a critical dimension in the range between 50 nanometers and 100s of micrometers, between 100 nanometers and 1 micrometer, between 1 micrometer and 10 micrometer, between 10 micrometer and 100 micrometer or any range fall within the range of 50 nanometers to 500 of micrometers.

58. The method of aspect 33, wherein the ratio of the height of the mesoscale heatsink feature to the width of the heatsink feature is between 1:3 and 3:1.

59. The mesoscale heatsink of aspect 1, wherein the features having a critical dimension in the range between 100 nanometers to 100 micrometers.

60. The mesoscale heatsink of aspect 1, wherein the features having a critical dimension in the range between 100 nanometers to 10 micrometers.

61. The mesoscale heatsink of aspect 1, wherein the features having a critical dimension in the range between 1 micrometer to 100 micrometers.

62. The method of aspect 24, wherein the features having a critical dimension in the range between 100 nanometers to 100 micrometers.

63. The method of aspect 24, wherein the features having a critical dimension in the range between 100 nanometers to 10 micrometers.

64. The method of aspect 24, wherein the features having a critical dimension in the range between 1 micrometer to 100 micrometers.

65. The method of aspect 31, further includes additional processes, such as apply thermal interface materials (TIMs), thermal spray coatings, electroplating, anodization or other surface treatment or coating to improve heat transfer.

66. The method of aspect 65, where the surface coating materials can be aluminum, copper, nickel, diamond-like carbon (DLC).

67. The device of aspect 34, wherein the features having a critical dimension in the range between 100 nanometers to 100 micrometers.

68. The device of aspect 34, wherein the features having a critical dimension in the range between 100 nanometers to 10 micrometers.

69. The device of aspect 34, wherein the features having a critical dimension in the range between 1 micrometer to 100 micrometers.

The embodiments were chosen and described to best explain the principles of the invention and its practical application to persons who are skilled in the art. As various modifications could be made to the exemplary embodiments, as described above with reference to the corresponding illustrations, without departing from the scope of the invention, it is intended that all matter contained in the foregoing description and shown in the accompanying drawings shall be interpreted as illustrative rather than limiting. Thus, the breadth and scope of the present invention should not be limited by any of the above-described exemplary embodiments, but should be defined only in accordance with the following claims appended hereto and their equivalents.

### Summary of Benefits and Applications

In summary, the present invention provides an improved mesoscale heatsink structure and its manufacturing method, which can effectively improve the heat dissipation efficiency of devices. The mesoscale heatsink structure can increase the surface area of the heatsink without taking up much space, which is particularly beneficial for applications with limited space. The structure can be customized to achieve optimal performance depending on the specific application and process capabilities. The aspect ratio of the mesoscale heatsink feature should be optimized for the best surface area increase, while maintaining good airflow for efficient heat dissipation.

The mesoscale heatsink structure can be easily integrated into existing device covers, components or heatsinks without significant manufacturing cost increase. The invention offers a practical and cost-effective solution to improve the thermal management of electronic devices, which can lead to better performance and reduced power consumption.

It is to be understood that the present invention is not limited to the embodiments described above, but encompasses any and all embodiments within the scope of the following claims. Therefore, various modifications and changes can be made to the invention without departing from the scope of the claims. The mesoscale heatsink structure can be applied to a wide range of devices, particular electronic devices and existing heatsinks, including but not limited to, CPUs, GPUs, power amplifiers, inverters, solar modules and other high-performance electronic components.

In addition to improving heat dissipation efficiency, the mesoscale heatsink structure can also lead to a reduction in noise generated by cooling fans. With the increased surface area of the heatsink, the airflow can be optimized to reduce turbulence and noise. The smaller size of the mesoscale heatsink also allows for more flexibility in the design of electronic devices, as it takes up less space.

The mesoscale heatsink structure can be integrated into existing devices' heat exchange units and improve their efficiency. This includes, but is not limited to, HVAC systems, furnaces, air handler units, fan coil units, and air exchange units. Regardless of the existing heatsink or heat exchange design utilized, the surface can be treated to have additional mesoscale heatsink features built in. Additionally, mesoscale heatsink features can be built on top of other mesoscale features. For example, a feature size with a couple of hundred nanometers may be built on top of a feature with a few tens of micrometers to further increase its surface area.

Overall, the mesoscale heatsink structure and its manufacturing method offer a promising solution to the thermal management challenges faced by electronic devices. By increasing the surface area of the heatsink, the mesoscale heatsink structure can improve the efficiency of heat dissipation, leading to better performance and reduced power consumption. Furthermore, the structure is cost-effective and can be easily integrated into existing device covers, components or heatsinks, making it an attractive option for manufacturers looking to improve the thermal management of their electronic products or any devices that need improved heat dissipation.

Modifications and variations may be made to the disclosed embodiments while remaining within the spirit and scope of the method, system, and apparatus. The implementations described above and other implementations are within the scope of the following claims.

What is claimed is:

1. A heatsink for dissipating heat from a device, comprising a mesoscale heatsink structure formed on a surface of the device, the conventional heatsink fin surfaces or the heat exchanger surfaces, with features having a critical dimension in the range of 50 nanometers to 100s of micrometers.

2. The mesoscale heatsink as claimed in claim 1, comprising at least one of a groove structure, a fin structure, a pin fin structure, a goosebump structure, a herringbone structure, a random waviness structure, or any other predefined feature structure to increase the surface area in contact with air for a given device surface.

3. The mesoscale heatsink as claimed in claim 1, wherein the critical dimension includes the width, height, and spacing between heatsink feature structures, as well as the roughness or height measured from the heatsink plane surface.

4. The mesoscale heatsink as claimed in claim 1, wherein the mesoscale heatsink structure includes a base coat and is further configured to include at least one of the following: doping with nano or micro particles or a polymer with high thermal conductivity.

5. The mesoscale heatsink as claimed in claim 4, wherein the base coat has a thickness between 1 and 100 micrometers.

6. The mesoscale heatsink as claimed in claim 4, wherein the doping particles have an average diameter ranging between 50 nanometers to 100s of micrometers.

7. The mesoscale heatsink as claimed in claim 4, wherein the average diameter of the doping particles exceeds the half of the thickness of the base coat.

8. The mesoscale heatsink as claimed in claim 4, wherein the doping particles can be made of various materials, including titanium oxide, aluminum oxide, zinc oxide, silicone dioxide, calcium carbonate, feldspar, iron oxide, limestone, magnesium carbonate (dolomite), silicon dioxide (SiO2), titanium dioxide (TiO2), iron oxide (Fe3O4), clay, iron carbonate, pyrite, quartz, different aluminum, iron, metallic alloys, metallic oxide, or a mixture of one or more of the above materials.

9. The mesoscale heatsink as claimed in claim 4, wherein the base coat also comprises binders based on one or more of the following: latex binders, 100% acrylic, styrene acrylic, or vinyl acrylic; Alkyd (oil) based binders such as linseed oil, tung oil, and soya oil, or other polymer-based adhesive materials.

10. A method of manufacturing a mesoscale heatsink structure for dissipating heat from a device, comprising: forming a mesoscale heatsink structure on a surface of the device, the conventional heatsink fin surfaces or the heat exchanger surfaces, wherein the mesoscale heatsink structure has a critical dimension in the range of between 50 nanometers to 100s of micrometers, and comprises at least one of: a groove structure, a fin structure, a pin fin structure, a herringbone structure, a goosebump structure, a random waviness structure, or any other predefined structure to increase the surface area in contact with air.

11. The method as claimed in claim 10, wherein the critical dimension includes the width, height, and spacing between heatsink structures, as well as the roughness or height measured from the heatsink plane surface.

12. The method as claimed in claim 10, wherein the mesoscale heatsink structure is formed by applying heatsink materials, including a base coat and doping particles or polymers with high thermal conductivity to create a heatsink structure.

13. The method as claimed in claim 12, wherein the doping particles have an average diameter ranging from 2 micrometers to 100 micrometers.

14. The method as claimed in claim 12, wherein the doping particles can be made of various materials, including titanium oxide, aluminum oxide, zinc oxide, silicone dioxide, calcium carbonate, feldspar, iron oxide, limestone, magnesium carbonate (dolomite), silicon dioxide (SiO2), titanium dioxide (TiO2), iron oxide (Fe3O4), clay, iron carbonate, pyrite, quartz, different aluminum and iron metallic alloys, metallic oxides, or a mixture of one or more of the above materials.

15. The method as claimed in claim 10, wherein the mesoscale heatsink structure is formed by using molds, laser engraving, stamping, pressing, chemical etching, powder coating, anodization, or hot pressing methods on the heatsink fin surface or device component surface with a desired texture or pattern.

16. A device comprising a mesoscale heatsink structure for dissipating heat, the heatsink structure comprising: a mesoscale heatsink structure formed on a surface of the device or attached to the heatsink of the device, the mesoscale heatsink structure having a critical dimension in the range of between 50 nanometers to 100s of micrometers, and comprising at least one of: a groove structure, a fin structure, a pin fin structure, a herringbone structure, a goosebump structure, a random waviness structure, or any other predefined structure to increase the surface area in contact with air.

17. The device as claimed in claim 16, wherein the surface with the mesoscale heatsink structure is a cover plate or is formed on device cover, such as for an HDD, an energy conversion device, an inverter, an optimizer, or a micro-inverter.

18. The device as claimed in claim 16, wherein the surface with the mesoscale heatsink structure is the backsheet for a solar module.

19. The device as claimed in claim 16, wherein the surface with the mesoscale heatsink structure is formed on top of existing heatsink structure or heat exchanger structure, such as the surface of the heatsink fins or heat exchanger surface such as used in HVAC (evaporator coils or condenser coils), furnace, fan coil unit, air handler unit or other air or liquid heatsinks etc.

20. The device as claimed in claim 16, wherein the mesoscale heatsink features can be formed on a larger existing mesoscale heatsink feature surface.
